(19) United States
(12) Patent Application Publication
(10) Pub. No.: US 2010/0203243 A1
(43) Pub. Date: Aug. 12, 2010

(54) METHOD FOR FORMING A POLYSILICON FILM

(75) Inventors: Ruiping Wang, Shanghai (CN); Ji Yue Tang, Shanghai (CN); Zhibiao Zhao, Shanghai (CN); Zhijun Fang, Shanghai (CN); Kailash Pradhan, Campbell, CA (US); Sean Michael Seutter, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 12/066,384

(22) PCT Filed: Dec. 27, 2007
(86) PCT No.: PCT/CN07/03841

§ 371 Date: May 3, 2010

(51) Int. Cl. C23C 16/44; C23C 16/42

(52) U.S. Cl. 427/255.28

(57) ABSTRACT

A method is provided for forming a poly-crystalline silicon film on a substrate. In one embodiment, the method comprises positioning a substrate within a processing chamber, heating the processing chamber to a deposition temperature, introducing a first silicon precursor into the processing chamber to form a buffer layer including crystal nuclei, introducing a second silicon precursor into the processing chamber to form a polysilicon film on the buffer layer, and then annealing the polysilicon film and the buffer layer.

### BACKGROUND OF THE INVENTION

1. Field of the Invention

Embodiments of the present invention relate to the field of electronic device fabrication and more specifically, to methods and apparatus for controlling the crystal structure of a polysilicon film.

2. Description of the Related Art

Poly-crystalline silicon films (also commonly called “polysilicon films”) formed by Low-Pressure Chemical Vapor Deposition (LPCVD) have wide use in the fabrication of integrated circuits and other electronic devices. Polysilicon film deposition processes require adequate physical, chemical, and production-worthy properties. For example, when the polysilicon film is to be formed on a dielectric layer as a gate electrode for a transistor of an integrated circuit, production-worthy properties requires uniform thickness and good interface between the polysilicon film and the dielectric layer. However, conventional methods for forming polysilicon films have difficulties achieving the increased uniformity and interface quality requirements currently set in the semiconductor manufacturing industry.

Therefore, there is a need for a method of forming a polysilicon film that meets advanced requirements with improved properties.

### SUMMARY OF THE INVENTION

Embodiments of the present invention generally provide a method for forming a polysilicon film on a substrate. In one embodiment, the method comprises positioning a substrate within a processing chamber, heating the processing chamber to a deposition temperature, introducing a first silicon precursor into the processing chamber to form a buffer layer including crystal nuclei, introducing a second silicon precursor into the processing chamber to form a polysilicon film on the buffer layer, and annealing the polysilicon film and the buffer layer.

In a further embodiment, another method for forming a polysilicon film on a substrate is disclosed. The method comprises positioning a substrate within a processing chamber, heating the processing chamber to a deposition temperature, introducing a first silicon precursor comprising SiH₄ into the processing chamber to form a buffer layer including crystal nuclei, introducing a second silicon precursor comprising Si₂H₆ at a first flow rate into the processing chamber to form a polysilicon film on the buffer layer, and then annealing the polysilicon film and the buffer layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional side view of a processing chamber according to one embodiment.

FIG. 2 is a block diagram of one embodiment of a process for forming a poly-crystalline silicon film on a substrate.

FIGS. 3A-3E illustrate a cross section of a substrate and the formation of a polysilicon film thereon according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein relate to a method for forming a polysilicon film. In particular, the embodiments relate to a method for forming a polysilicon film with improved uniformity and interface quality.

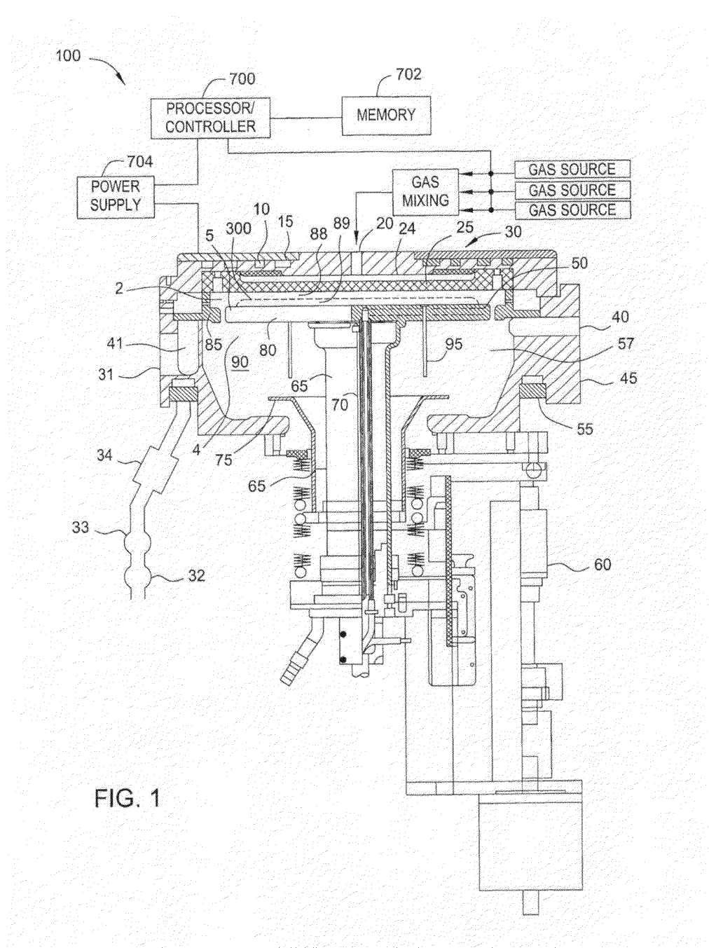

FIG. 1 illustrates one embodiment of an apparatus that may be used to practice embodiments of the method. An example of a chamber that may be used is the POLYGEN CENTURA® chemical vapor deposition (CVD) chamber, commercially available from Applied Materials, Inc. of Santa Clara, Calif. In one particular embodiment, the apparatus may be a LPCVD chamber 100. The LPCVD chamber 100 illustrated in FIG. 1 is constructed of materials to maintain, in one embodiment, a deposition chamber pressure between about 200 Torr and about 350 Torr and a deposition chamber temperature between about 600° C. and about 800 C. For the purpose of illustration, the LPCVD chamber 100 may have a chamber volume of about 5-6 liters. FIG. 1 illustrates the inside of the process chamber body 45 in a “substrate-process” position. A substrate 300 is indicated in dashed lines to indicate its location in the LPCVD chamber 100. In one embodiment, the LPCVD chamber 100 is adapted to hold one substrate only (i.e., a single substrate chamber). The chamber body 45 may be sized to accommodate a substrate having a diameter between about 200 mm and about 400 mm.

The chamber body 45 defines a reaction chamber 90 in which the thermal decomposition of a process gas or gases takes place to form a nano-crystal polysilicon film on a substrate 300. The chamber body 45 may be constructed of an aluminum material and has a passage 55 for water to be pumped therethrough, for example, within the chamber walls, to isolate the reaction area around the substrate 300 and prevent deposition on the inside walls of the chamber 45. In one embodiment, the LPCVD chamber 100 may be a “cold-wall” reaction chamber. Resident in reaction chamber 90 is a resistive heater 80 including a susceptor 5 supported by shaft 65. The susceptor 5 has a surface area sufficient to support a substrate such as the semiconductor substrate 300 (shown in dashed lines). The substrate 300 may have any surface, generated when making an integrated circuit, upon which a conductive layer may be formed. The substrate 300 thus may include, for example, active and passive devices that are formed on its surface, such as transistors, capacitors, resistors, diffused junctions, gate electrodes, local interconnects, etc.

FIG. 1 also illustrates a cross-sectional view of a portion of the heater 80, including a cross-section of the body of the susceptor 5 and a cross-section of a shaft 65. As shown, the body of the susceptor 5 may have two heating elements formed therein, such as a first heating element 50 and a second heating element 57. Each heating element (e.g., the heating element 50 and 57) is made of a material with thermal expansion properties similar to the material of the susceptor 5. In one embodiment, the material for the susceptor 5 may include molybdenum (Mo), or other suitable materials known in the art. The first and second heating elements 50, 57 also include a thin layer of molybdenum material in a coiled configuration. The dual heater system of the LPCVD chamber 100 provides the advantage of allowing for a precise control of the deposition temperature for the nano-crystal polysilicon film. In an alternative embodiment, the LPCVD chamber 100 may include lamp heaters instead of the resistive type heaters described above with respect to the heating elements 50 and 57.

The LPCVD chamber 100 allows for a precise control of the temperature and pressure of the deposition environment. In one embodiment, the heater 80 with the heating elements 50 and 57 allow for a precise temperature control and stability. The passage of a process gas through a blocker plate 24 and a perforated face plate 25 provides the advantage of a uniform gas distribution towards the substrate 300. Suitable materials for the reaction chamber 90 should be compatible with the process gases and other chemicals, such as cleaning chemicals (e.g., nitrogen trifluoride, NF₃) that may be introduced into the reaction chamber 90.

The exposed surfaces of the heater 80 may be comprised of a variety of materials provided that the materials are compatible with the process gases. For example, the susceptor 5 and the shaft 65 of the heater 80 may be comprised of similar aluminum nitride material. Alternatively, the surface of the susceptor 5 may be comprised of high thermally conductive aluminum nitride materials (in the order of about 95% purity with a thermal conductivity from about 140 W/mK, in one embodiment) while the shaft 65 is comprised of a lower thermally conductive aluminum nitride. In one embodiment, the susceptor 5 of the heater 80 may be coupled to the shaft 65 by diffusion bonding or brazing, because this type of coupling may withstand the environment of the reaction chamber 90.

In FIG. 1, the second heating element 57 is formed in a plane of the body of the susceptor 5 that is disposed lower (relative to the surface of the susceptor 5 in the figure) than the first heating element 50. The first heating element 50 and second heating element 57 are separately coupled to power terminals. The power terminals extend in a lower direction as conductive leads through a longitudinally extending opening through the shaft 65 to a power source that supplies the requisite energy to heat the surface of the susceptor 5. Extending through openings in the chamber lid 30 are two pyrometers, such as a first pyrometer 10 and second pyrometer 15. Each pyrometer provides data about the temperature on the surface of the susceptor 5 (or on the surface of a substrate on the susceptor 5). A thermocouple 70 may be positioned in the cross-section of the heater 80. The thermocouple 70 extends through the longitudinally extending opening through the shaft 65 to a point just below the top surface of the susceptor 5.

A process gas may enter the otherwise sealed reaction chamber 90 through a gas distribution port 20 in a top surface of the chamber lid 30 of the chamber body 45. The process gas may then go through the blocker plate 24 to distribute the gas about an area consistent with the surface area of the substrate 300. Thereafter, the process gas may be distributed through the perforated face plate 25 located above the resistive heater 80 and coupled to the chamber lid 30 inside the reaction chamber 90. In one embodiment, the combination of the blocker plate 24 with the face plate 25 creates a uniform distribution of process gas near a top surface of the substrate 300.

As illustrated, the substrate 300 may be placed in the reaction chamber 90 on the susceptor 5 of the heater 80 through an entry port 40 in a side portion of the chamber body 45. To accommodate a substrate for processing, the heater 80 is lowered so that the surface of the susceptor 5 is below the entry port 40. In one embodiment, the substrate 300 may be loaded into the reaction chamber 90 by way of, for example, a transfer blade of a robotic transfer mechanism (not shown) onto the top surface of the susceptor 5. Once the substrate 300 is loaded, the entry 40 is sealed and the heater 80 is advanced in an upward direction toward the face plate 25 by a lifter assembly 60 that may include, for example, a stepper motor. The advancement stops when the substrate 300 is a short distance (e.g., 400-700 mils) from the face plate 25. In the substrate-process position of FIG. 1, the reaction chamber 90 is divided into two zones, a first zone 2 above the top surface of the susceptor 5 and a second zone 4 below the bottom surface of the susceptor 5.

With the substrate 300 disposed within the reaction chamber 90, the first zone 2 includes an area 88 above the substrate 300 where a nano-crystal polysilicon film is formed on the top surface of the substrate 300 (i.e., the substrate surface facing the perforated face plate 25). That is, nano-crystal polysilicon film deposition is limited to one side of the substrate 300. In one embodiment, the area 88 defines a partial pressure area in the reaction chamber 90 (i.e., (flow rate of precursor/total flow)×chamber pressure) for a gas source such as a silicon precursor. In an alternative embodiment, nano-crystal polysilicon formation may be accomplished in both the first and second zones for silicon film deposition on both sides of the substrate 300. Accordingly, the area 88 and area 89, corresponding to the top and bottom surfaces of the substrate 300, defines the partial pressure area for dual sided deposition.

The process gas, which flows into the reaction chamber 90 under the control of a gas panel, may be thermally decomposed to form a film on the substrate. At the same time, an inert bottom-purge gas, e.g., nitrogen, may be introduced into the second chamber zone to inhibit film formation in that zone. In a pressure controlled system, the pressure in the reaction chamber 90 may be established and maintained by a pressure regulator or regulators (not shown) coupled to the reaction chamber 90. In one embodiment, for example, the pressure is established and maintained by one or more baratron pressure regulator(s) coupled to the chamber body 45 as known in the art. In one embodiment, the baratron pressure regulator(s) maintains pressure at a level between about 200 Torr to about 350 Torr and a temperature between about 600° C. and 800° C. for the deposition of a nano-crystal polysilicon film on the substrate 300.

Residual process gas may be pumped out of the reaction chamber 90 through a pumping plate 85 to a collection vessel at a side of the chamber body 45 (vacuum pump-out 31). The pumping plate 85 may create two flow regions resulting in a gas flow pattern that forms a poly-crystalline silicon layer on the substrate 300.

A pump 32 disposed outside the reaction chamber 90 may provide vacuum pressure within a pumping channel 41 to draw both the process and purge gases out of the reaction chamber 90 through the vacuum pump-out 31. The gas is discharged from the reaction chamber 90 along a discharge conduit 33. The flow rate of the discharge gas through the channel 41 may be controlled by a throttle valve 34 disposed along the discharge conduit 33. In one embodiment, the pressure within the reaction chamber 90 is monitored with sensors (not shown) and controlled by varying the cross-sectional area of the conduit 33 with the throttle valve 34. Preferably, a controller or processor (not shown) receives signals from the sensors that indicate the chamber pressure and adjusts the throttle valve 34 accordingly to maintain the desired pressure within the reaction chamber 90.

Once the processing of the substrate 300 is complete, the reaction chamber 90 may be purged, for example, with an inert gas, such as nitrogen. After processing and purging, the heater 80 is lowered by the lifter assembly 60. As the heater 80 is moved, lift pins 95, having an end extending through openings or throughbores in a surface of the susceptor 5 and a second end extending in a cantilevered fashion from a lower surface of the susceptor 5, contact a lift plate 75 positioned at the base of the reaction chamber 90. In one embodiment, the lift plate 75 remains at a substrate-process position. As the heater 80 continues to move downward driven by the lifter assembly 60, the lift pins 95 remain stationary and ultimately extend above the susceptor or top surface of the susceptor 5 to separate the processed substrate 300 from the surface of the susceptor 5. The surface of the susceptor 5 is thereby moved to a position below the entry port 40.

Once a processed substrate 300 is separated from the surface of the susceptor 5, the transfer blade of a robotic mechanism may be moved through the opening 40 beneath the top ends of the lift pins 95 that supports the substrate 300. Next, the lifter assembly 60 further moves downward the heater 80 and the lift plate 75 to a “substrate load” position. By moving the lift plates 75 downward, the lift pins 95 are also moved downward until the surface of the processed substrate 300 contacts the transfer blade (not shown). The processed substrate 300 may then be retrieved through the entry port 40 and transferred to the next processing stage. A second substrate (not shown) may then be loaded into the reaction chamber 90 for processing. The steps described above then may be reversely performed to bring the new substrate 300 into a process position.

The LPCVD chamber 100 may include a processor/controller 700 and a memory 702, such as a hard disk drive. The processor/controller 700 may include a single board (SBC) analog and digital input/output boards, interface boards and stepper motor controller board and is coupled to a power supply 704. The processor/controller 700 may be configured to supervise and monitor the operation the LPCVD chamber 100. The controller 700 executes system control software, which is a computer program stored in a computer readable medium such as the memory 702. The computer readable medium includes any mechanism that provides (i.e., stores and/or transmits) information in a form accessible by a machine (i.e., a computer, network device, personal digital assistant, manufacturing tool such as a single substrate deposition chamber, any device with a set of one or more processors, etc.). For example, a computer readable medium includes recordable/non-recordable media (e.g., read only memory (ROM); random access memory (RAM); magnetic disk storage media; optical storage media; flash memory devices, etc.), as well as electrical, optical, acoustical or other form of propagated signals (e.g., carrier waves, infrared signals, digital signals, etc.).

The computer program may include sets of instructions that control the timing, mixture of gases, chamber pressure, heater temperature, power supply (e.g., 704), susceptor position, and other parameters for the nano-crystal polysilicon deposition process. The computer program code can be written in any conventional computer readable programming language such as 68000 assembly language, C, C++, Pascal, Fortran, or others. Subroutines for carrying out process gas mixing, pressure control, and heater control may be stored within the memory 702. The memory 702 also stores process parameters such as process gas flow rates and compositions, temperatures, and pressures necessary to form a polysilicon film. In one embodiment, the LPCVD chamber 100 includes in memory 702 instructions and process parameters for delivering a gas mixture including a silicon source gas and a carrier gas into the reaction chamber 90, heating the susceptor 5 to a temperature between about 640° C. and about 750° C., and generating a pressure between about 200 Torr to about 350 Torr within the reaction chamber 90 so that a polysilicon film may be deposited by thermal chemical vapor deposition onto the substrate 300.

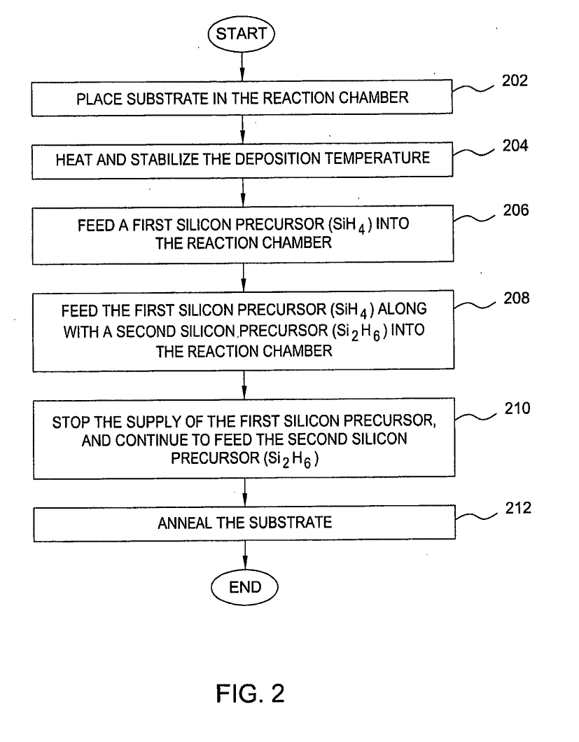

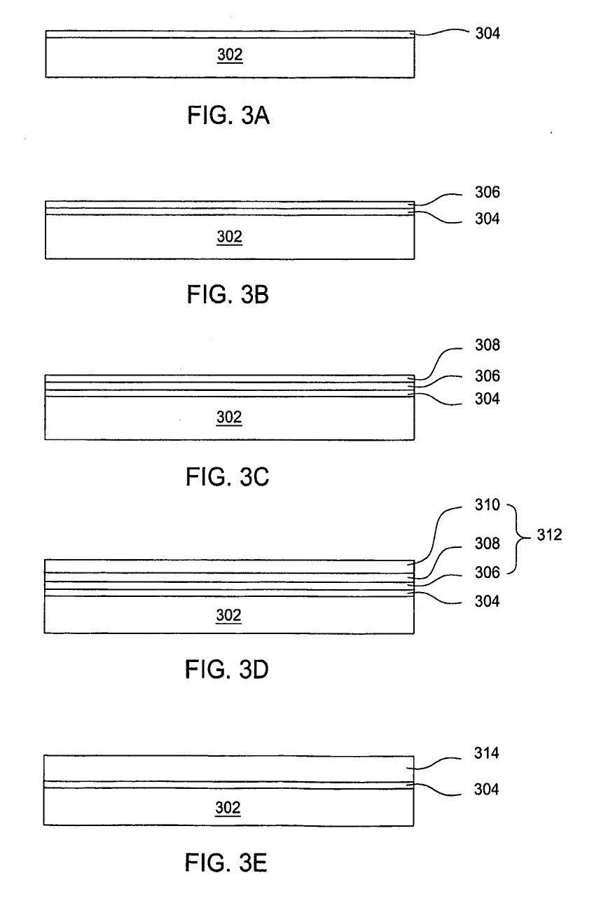

FIG. 2 is a flowchart of method steps implemented in one embodiment of a deposition process for forming a polysilicon film on a substrate, which are described in conjunction with the cross-sectional views of FIGS. 3A-3E. In one embodiment, the deposition process may be performed in the single substrate LPCVD chamber 100 shown in FIG. 1.

In initial step 202, a substrate is placed in the reaction chamber 90. In one embodiment where the deposited polysilicon film is to be used as a gate electrode for a transistor of a semiconductor integrated circuit, the substrate may be a silicon substrate 302 having a gate dielectric layer 304, such as silicon oxide or silicon oxynitride formed thereon as illustrated in FIG. 3A. Dopants may be incorporated in the deposited polysilicon film to confer a desired conductivity. Examples of dopants include, but are not limited to, germane (GeH₄), phosphine (PH₃), and diborane (B₂H₆). In one embodiment, the dopants may be introduced in situ along with the silicon precursor gas so that no separate doping procedure is required (i.e., the dopant is delivered with the carrier gas. The substrate is transferred into the chamber by a transfer blade. The heater 80 is then raised from the substrate load position to the substrate process position as shown in FIG. 1.

In step 204, the desired deposition temperature is obtained and stabilized in the chamber 90. In one embodiment, the deposition temperature of the chamber may be set between about 650° C. and about 750° C., preferably about 700° C.

In step 206, a first silicon precursor gas is then fed into the chamber 90. In one embodiment, the first silicon precursor gas comprises silane (SiH₄). The flow of the precursor gas is limited to the area 88 above the top surface of the substrate 302 for deposition of silicon on one side of the substrate 300. SiH₄ may be fed at a flow rate between about 40 sccm (standard cubic centimeters per minute) and about 200 sccm, while the deposition pressure is set between about 50 Torr and 275 Torr. A carrier gas or dilution gas may be introduced along with the first precursor gas into the chamber 90. In one embodiment, the carrier or dilution gas may be nitrogen or argon. Step 206 is conducted for a period of time to deposit a buffer layer 306 over the substrate surface, as shown in FIG. 3B. The formed buffer layer 306 includes crystal nuclei that contribute to improve the interface quality between a subsequent layer and the dielectric layer 304.

In transition step 208, in addition to the first silicon precursor gas, a second silicon precursor gas is fed into the chamber 90. A carrier gas (e.g., nitrogen, helium, or argon) may be introduced with the second silicon precursor gas. In one embodiment, the second silicon precursor gas comprises disilane (Si₂H₆). Si₂H₆ is fed at a flow rate between about 30 sccm and about 60 sccm, and SiH₄ is fed at a flow rate between about 40 sccm and about 200 sccm. In the meantime, the deposition pressure is kept between about 50 Torr and about 275 Torr. Step 208 thereby forms a transition layer 308 on the buffer layer 306.

In following step 210, while the supply of the first silicon precursor gas is turned off, the second silicon precursor gas (e.g. Si₂H₆) is kept flowing into the chamber 90. Si₂H₆ is fed at a flow rate between about 30 sccm and about 100 sccm, and the deposition pressure is set between about 30 Torr and about 280 Torr. As a result, a corresponding polysilicon layer 310 is formed on the transition layer 308. The polysilicon layer 310 is formed as the bulk portion of a polysilicon film 312 to deposit on the substrate 302. The duration of step 210 may depend on the total thickness required for the polysilicon film 312. Due to the presence of the buffer layer 304, a good interface is provided between the polysilicon film 312 and the dielectric layer 304. In addition, the bulk portion 310 formed with Si₂H₆ precursor gas provide better uniformity. In one embodiment, the second silicon precursor may be supplied for about 10 seconds to about 40 seconds.

The polysilicon film 312 thereby formed may be in an amorphous or hemispheric grain (HSG) state. In addition, a dopant precursor gas may also be introduced into the chamber 90 so that the polysilicon film 312 is conferred with a desired conductivity. Any suitable dopant precursor may be used, such as BCl₃ for boron doping and PH₃ for phosphorous doping. The dopant precursor flow may be between about 20 sccm and about 130 sccm.

Step 212 is an annealing and purge step in which the substrate 302 is heated to a temperature between about 700° C. and about 750° C., preferably, between about 720° C. and about 740° C. An inert gas (e.g., nitrogen, helium, argon) may be flowed into the chamber 90 during the annealing step. As the temperature of the substrate 302 rises, kinetic energy is generated inside the polysilicon film 312 to convert the polysilicon film 312 in the amorphous or HSG state into a polysilicon film 314 comprised of nano-crystal grains, as illustrated in FIG. 3E. Although not bound by this theory, the anneal temperature provides sufficient kinetic energy for nano-crystal grains to be grown around the crystal nuclei of the polysilicon film 312. Furthermore, the energy the Si atoms obtain through the annealing step enables the atoms to migrate, so that the particles obtain a surface roughness of less than about 30 Å. Typically the roughness of a one step deposition HSG particle is about 55 Å.

Step 212 may be performed in the same substrate processing chamber as the LPCVD process, such as in the single substrate LPCVD chamber 100 of FIG. 1. Alternatively, annealing step 212 may be performed in a separate annealing chamber, such as in an RTP chamber such as the RADIANCE CENTURA® system, commercially available from Applied Materials, Inc, in Santa Clara, Calif.

### EXAMPLE

The following example illustrates the deposition of a polysilicon film on a silicon substrate having a silicon oxide gate dielectric layer. The polysilicon film is formed according to the process described above in a POLYGEN CENTURA® CVD chamber.

First, an initial buffer layer is deposited on the substrate surface. To deposit the initial buffer layer over the substrate surface, a first silicon precursor is fed for about 5 seconds to about 15 seconds to the process chamber. The gas mixture comprises SiH₄ at a flow rate of about 40 sccm to 200 sccm. A carrier gas is also supplied to the process chamber. The carrier gas comprises nitrogen and is supplied to the process chamber at a flow rate of about 15 standard liters per minute (mls) above the heater, and at a flow rate of about 6 mls below the heater. It has been observed that providing carrier gas from above and below the heater during deposition improves film uniformity. The process chamber has a pressure set between about 50 Torr and 275 Torr, a temperature between about 650° C. to about 750° C., and a heater spacing between about 450 mils to 700 mils.

A transition step follows the initial buffer layer deposition. During the transition step, Si₂H₆ is additionally introduced along with SiH₄ for about 5 seconds to about 15 seconds. The Si₂H₆ is supplied at a flow rate of about 30 sccm to 60 sccm, while SiH₄ has a flow rate of about 40 sccm to 200 sccm. The process chamber has a pressure set between about 50 Torr and 275 Torr and a temperature at about 700° C. The carrier gas is supplied to the process chamber at a flow rate of about 15 standard liters per minute (mls) above the heater, and at a flow rate of about 6 mls below the heater. The process chamber has a pressure set between about 50 Torr and 275 Torr, a temperature between about 650° C. to about 750° C., and a heater spacing between about 450 mils to about 700 mils.

A deposition step follows the transition step. In the deposition step, the supply of SiH4 is turned off, and Si₂H₆ is continuously fed for about 10 seconds to 40 seconds at a flow rate of about 30 sccm to 100 sccm to complete the deposition of the polysilicon film. During the deposition step, the carrier gas is supplied to the process chamber at a flow rate of about 15 standard liters per minute (mls) above the heater, and at a flow rate of about 6 mls below the heater. The process chamber has a pressure set between about 50 Torr and 275 Torr, a temperature between about 650° C. to about 750° C., and a heater spacing between about 450 mils to about 700 mils.

A purge and anneal step follows the deposition step. During the purge and anneal step, the flow of silicon precursor Si₂H₆ is turned off. The chamber temperature is increased to about 670° C. to about 770° C. at ramp of about 0.2° C./second. During the purge and anneal step, a throttle valve to the process chamber is fully open and a carrier gas, nitrogen, is supplied to the process chamber at a flow rate of about 4 standard liters per minute (mls) above the heater, and at a flow rate of about 2 mls below the heater. The substrate then is heated at the increase temperature, (about 670° C. to about 770° C.) for about 30 seconds. The heater spacing remains at between about 450 mils to about 700 mils.

As has been described, the method and apparatus described herein thus are able to form a polysilicon film with good thickness uniformity and interface quality with a dielectric layer by using two different silicon precursor gases, e.g. SiH₄ and Si₂H₆.

While the embodiments illustrated herein describe specific temperature, pressure and gas flow rate conditions for forming the polysilicon film, these conditions may be modified to fine tuned desired properties of the polysilicon film. For example, the properties of the interface between the polysilicon film and the dielectric layer may be changed by modifying the temperature, pressure and gas flow rate applied for forming the buffer layer 306. Moreover, the crystal grain size of the polysilicon film may be tuned by adjusting the deposition conditions applied for forming the layers 308 and 310.

While the foregoing is directed to embodiments of the present invention, other and further embodiments of the invention thus may be devised without departing from the basic scope thereof, and the scope thereof is determined by the claims that follow.

1. A method for forming a polysilicon film on a substrate, comprising:
positioning a substrate within a processing chamber;
heating the processing chamber to a deposition temperature;
introducing a first silicon precursor into the processing chamber to form a buffer layer including crystal nuclei;
introducing a second silicon precursor into the processing chamber to form a polysilicon film on the buffer layer; and
annealing the polysilicon film and the buffer layer.

2. The method of claim 1, wherein the first silicon precursor comprises silane (SiH₄).

3. The method of claim 1, wherein the second silicon precursor comprises disilane (Si₂H₆).

4. The method of claim 1, wherein the first silicon precursor comprises silane (SiH₄) and the second silicon precursor comprises disilane (Si₂H₆).

5. The method of claim 4, further comprising introducing a carrier gas into the processing chamber along with the first and second silicon precursors.

6. The method of claim 5, wherein the carrier gas comprises at least one of nitrogen and argon.

7. The method of claim 4, wherein the first silicon precursor has a flow rate between about 40 sccm and about 200 sccm.

8. The method of claim 7, wherein the second silicon precursor has a flow rate between about 30 sccm and 100 sccm.

9. The method of claim 8, wherein the deposition temperature is about 700° C.

10. The method of claim 9, wherein the first silicon precursor is introduced at a deposition pressure between about 50 Torr and about 275 Torr.

11. The method of claim 10, wherein the second silicon precursor is introduced at a deposition pressure between about 30 Torr and 280 Torr.

12. The method of claim 11, wherein the buffer layer is formed on a dielectric layer of the substrate.

13. The method of claim 1, wherein introducing a second silicon precursor into the processing chamber comprises introducing the second silicon precursor concurrently to introducing the first silicon precursor into the processing chamber over a transition period of time.

14. The method of claim 13, further comprising turning off the flow of the first silicon precursor after the transition period of time, and increasing the flow rate of the second silicon precursor.

15. The method of claim 1, wherein introducing a first silicon precursor into the processing chamber is performed over a period of time between about 5 seconds and 15 seconds.

16. A method for depositing a polysilicon film on a substrate, comprising:
positioning a substrate in an internal volume of a processing chamber;
heating the substrate to a deposition temperature;
flowing in a first silicon precursor to form a buffer layer including crystal nuclei on the substrate, wherein the first silicon precursor comprises SiH₄; and
flowing in a second silicon precursor at a first flow rate, wherein the second silicon precursor comprises Si₂H₆.

17. The method of claim 16, further comprising flowing a carrier gas along with the first and second silicon precursors.

18. The method of claim 17, wherein the carrier gas comprises at least one of nitrogen and argon.

19. The method of claim 16, wherein the first silicon precursor has a flow rate between about 40 sccm and about 200 sccm.

20. The method of claim 16, wherein the first flow rate of the second silicon precursor is between about 30 sccm and about 60 sccm.

21. The method of claim 16, further comprising terminating the flow of the first silicon precursor, and flowing the second silicon precursor at a second flow rate.

22. The method of claim 21, wherein the second flow rate of the second silicon precursor is between about 30 sccm and 100 sccm.

23. The method of claim 21, wherein the second silicon precursor is fed at a deposition pressure between about 30 Torr and about 280 Torr.

24. The method of claim 16, wherein the deposition temperature is about 700° C.

25. The method of claim 16, wherein the first silicon precursor is flowed in the processing chamber at a deposition pressure between about 50 Torr and about 275 Torr.
